(19) United States
(12) Patent Application Publication
(10) Pub. No.: US 2025/0192020 A1
(43) Pub. Date: Jun. 12, 2025

(54) CIRCUIT BOARD AND METHOD OF FABRICATING CIRCUIT BOARD

(71) Applicant: SAMSUNG ELECTRO-MECHANICS CO., LTD., Suwon-si (KR)

(72) Inventors: Youngwoong Cho, Suwon-si (KR); Heun Young Seo, Suwon-si (KR)

(73) Assignee: SAMSUNG ELECTRO-MECHANICS CO., LTD., Suwon-si (KR)

(21) Appl. No.: 18/666,165

(22) Filed: May 16, 2024

(30) Foreign Application Priority Data
Dec. 7, 2023 (KR) 10-2023-0177107

(51) Int. Cl. H01L 23/498; H01L 21/48

(52) U.S. Cl. CPC H01L 23/49838; H01L 21/4846

(57) ABSTRACT

A circuit board includes: an insulating layer having a first surface and a second surface opposing each other; and a first connection pad having a first portion embedded in the insulating layer and at least partly exposed from the insulating layer on the first surface and a second portion closer to the second surface than the first portion. A first width of the first portion in a direction parallel to the first surface is different from a second width of the second portion in the direction parallel to the first surface.

### CROSS-REFERENCE TO RELATED APPLICATION

This application claims priority to and the benefit of Korean Patent Application No. 10-2023-0177107 filed in the Korean Intellectual Property Office on Dec. 7, 2023, the entire contents of which are incorporated herein by reference.

### TECHNICAL FIELD

The present disclosure relates to a circuit board and a method of fabricating the circuit board.

### BACKGROUND

In the semiconductor package fabricating process using a lead frame, the chip attaching process, which mounts a semiconductor chip on the lead frame, is followed by a wire bonding process, which electrically connects the semiconductor chip and the lead frame with a metal thin wire. The wire bonding process is carried out by, for example, using ultrasonic waves to cause a local fusion phenomenon to bond metal wires on a metal pad layer of the semiconductor chip.

As the electronic industry develops and the down-sizing and high-performance of electronic devices accelerate, the size of the semiconductor packages also tends to become smaller. To respond to the down-sizing of package products, the size of the bonding pad of the printed circuit board (PCB) for wire bonding is also being reduced. On the other hand, to reduce the bonding defect rate during the wire bonding process, the bonding pad width is required to be expanded when fabricating the printed circuit board (PCB).

### SUMMARY

The present disclosure attempts to provide a circuit board for realizing a bonding pad for mounting a wire bonding chip in a fine pitch pattern and obtaining a width of a bonding pad to which a bonding wire is connected, and a method for fabricating a circuit board.

The object of the present disclosure is not limited to the above-described object, and it may be expanded in various ways in the range of the ideas and the areas of the present disclosure.

An embodiment of the present disclosure provides a circuit board including: an insulating layer having a first surface and a second surface opposing each other; and a first connection pad having a first portion embedded in the insulating layer and at least partly exposed from the insulating layer on the first surface and a second portion closer to the second surface than the first portion. A first width of the first portion in a direction parallel to the first surface is different from a second width of the second portion in the direction parallel to the first surface.

The first width may be greater than the second width.

The first portion and the second portion may be configured to have a step.

The circuit board may further include a protection layer disposed on the first surface of the insulating layer and having an opening to expose the first connection pad.

The circuit board may further include a first circuit wiring embedded in the insulating layer and covered with the protection layer. A thickness of the first circuit wiring in a direction perpendicular to the first surface may be greater than a thickness of the first portion of the first connection pad in the direction perpendicular to the first surface.

The circuit board may further include a conductive layer disposed on the first connection pad.

The conductive layer may be disposed on the exposed portion of the first connection pad.

The conductive layer may protrude on the first surface of the insulating layer.

A width of the conductive layer in the direction parallel to the first surface may be greater than the second width of the second portion of the first connection pad.

A width of the conductive layer in the direction parallel to the first surface may be equal to or greater than the first width of the first portion of the first connection pad.

The conductive layer may include a gold (Au) plating layer.

The first connection pad may include copper (Cu).

The first connection pad may be disposed in a bond finger region.

The circuit board may further include a second connection pad disposed on the second surface of the insulating layer.

The insulating layer may include a plurality of insulating layers, and the circuit board may further include a plurality of circuit layers disposed in or on the plurality of insulating layers.

Another embodiment of the present disclosure provides a method for fabricating a circuit board including: forming a first portion of a first connection pad with a first metal on a seed layer; forming a second portion of the first connection pad having a different width from the first portion on the first portion by patterning plating resist covering a portion of the first portion and plating the first metal; and forming an insulating layer to cover the first portion and the second portion.

A first width of the first portion may be formed to be greater than a second width of the second portion.

The method may further include removing the seed layer to expose at least a portion of the first portion from the insulating layer.

The method may further include forming a conductive layer on the first portion exposed from the insulating layer.

The method may further include forming, on the insulating layer, a protection layer having an opening to expose the conductive layer.

According to the circuit board according to the embodiments, the bonding pad for mounting the wire bonding chip may be implemented in a fine pitch pattern while securing a wide width of the bonding pad to which the bonding wire is connected. By securing the width of the bonding pad, the bonding pad miss defects may be improved during packaging. In addition, the width of the pad embedded in the insulating layer is designed to be relatively narrow to increase design freedom and react to the bond finger with fine pitches caused by package down-sizing.

According to the method for fabricating a circuit board according to the embodiments, it is possible to secure the width of the connection surface of the bonding wire while maintaining the bonding pad in a fine pitch pattern by fabricating it using the embedded trace substrate (ETS) method.

### BRIEF DESCRIPTION OF THE DRAWINGS

FIG. 1 shows a cross-sectional view on a circuit board according to an embodiment.

FIG. 2 to FIG. 15 show process cross-sectional views of a method for fabricating a circuit board shown in FIG. 1.

### DETAILED DESCRIPTION OF THE EMBODIMENTS

In the following detailed description, only certain embodiments of the present disclosure have been shown and described, simply by way of illustration. The drawings and description are to be regarded as illustrative in nature and not restrictive. Like reference numerals designate like elements throughout the specification. Some constituent elements are exaggerated, omitted, or briefly illustrated in the added drawings, and sizes of the respective constituent elements do not reflect the actual sizes.

The accompanying drawings are provided only in order to allow embodiments disclosed in the present specification to be easily understood and are not to be interpreted as limiting the spirit disclosed in the present specification, and it is to be understood that the present disclosure includes all modifications, equivalents, and substitutions without departing from the scope and spirit of the present disclosure.

Terms including ordinal numbers such as first, second, and the like will be used only to describe various constituent elements, and are not to be interpreted as limiting these constituent elements. The terms are only used to differentiate one constituent element from other constituent elements.

It will be understood that when an element such as a layer, film, region, or substrate is referred to as being “on” another element, it may be directly on the other element or intervening elements may also be present. In contrast, when an element is referred to as being “directly on” another element, there are no intervening elements present. The word “on” or “above” means positioned on or below the object portion, and does not necessarily mean positioned on the upper side of the object portion based on a gravitational direction.

It should be understood that the term “include”, “comprise”, “have”, or “configure” indicates that a feature, a number, a step, an operation, a constituent element, a part, or a combination thereof described in the specification is present, but does not exclude a possibility of presence or addition of one or more other features, numbers, steps, operations, constituent elements, parts, or combinations, in advance. Unless explicitly described to the contrary, the word “comprise” and variations such as “comprises” or “comprising” will be understood to imply the inclusion of stated elements but not the exclusion of any other elements.

The phrase “in a plan view” or “on a plane” means viewing a target portion from the top, and the phrase “in a cross-sectional view” or “on a cross-section” means viewing a cross-section formed by perpendicularly cutting a target portion from the side.

Throughout the specification, when it is described that a part is “connected” to another part, the part may be “directly connected” to the other element, may be “connected” to the other part through a third part, or may be connected to the other part physically or electrically, and may be referred to by different titles depending on positions or functions, but respective portions that are substantially integrated into one body may be connected to each other.

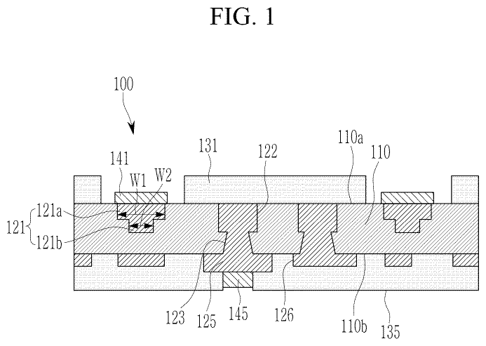

FIG. 1 shows a cross-sectional view on a circuit board according to an embodiment.

Referring to FIG. 1, the circuit board 100 may include an insulating layer 110 and a first connection pad 121 and a first circuit wiring 122 embedded in the insulating layer 110. The insulating layer 110, the first connection pad 121, and the first circuit wiring 122 may configure an embedded pattern substrate. The circuit board 100 is a printed circuit board (PCB) and may be used for the semiconductor package.

The insulating layer 110 may have a first surface 110a and a second surface 110b opposing each other, and may include a resin insulating layer. The insulating layer 110 may use a thermo-curable resin such as an epoxy resin, a thermoplastic resin such as a polyimide, or a resin, e.g., a prepreg, to which a reinforcing member such as glass fibers or an inorganic filler is impregnated, and may include a thermo-curable resin and/or a photocurable resin, and it is not limited thereto.

The first connection pad 121 may be embedded in the insulating layer 110, and have different widths at an upper portion and a lower portion. The first connection pad 121 embedded in the insulating layer 110 may include a first portion 121a disposed close to the first surface 110a of the insulating layer 110 and a second portion 121b disposed close to the second surface 110b. At least a portion of the first portion 121a may be exposed from the insulating layer 110 on the first surface 110a, and the second portion 121b may be disposed closer to the second surface 110b than the first portion 121a.

A first width W1 of the first portion 121a may be greater than a second width W2 of the second portion 121b with respect to a width of the insulating layer 110 measured in a parallel direction to the first surface 110a. The first width W1 of the first portion 121a exposed from the insulating layer 110 may be greater than the second width W2 of the second portion 121b. In this instance, the first portion 121a and the second portion 121b of the first connection pad 121 may respectively have a structure with steps. Hence, the first connection pad 121 embedded in the insulating layer 110 may realize the bonding pad with fine pitches and may secure a wide surface area on which the wire bonding is performed, thereby reducing bonding errors.

The first conductive layer 141 may be stacked on the first connection pad 121. The first conductive layer 141 may be disposed on the first portion 121a of the first connection pad 121 exposed from the insulating layer 110. The exposed first portion 121a of the first connection pad 121 may form a same plane as the first surface 110a of the insulating layer 110 or may be formed to be slightly dented in the first surface 110a of the insulating layer 110. The first conductive layer 141 stacked on the first connection pad 121 may at least partly protrude on the first surface 110a of the insulating layer 110.

The first connection pad 121 and the first circuit wiring 122 may include a copper (Cu) layer. The first conductive layer 141 may include a nickel (Ni) plating layer and a gold (Au) plating layer. The first conductive layer 141 may be formed by plating the nickel plating layer on the first connection pad 121 and plating the gold plating layer on the nickel plating layer.

In the present embodiment, the first conductive layer 141 may be formed by a gold electroplating method. That is, the nickel plating layer and the gold plating layer may be formed by forming nickel/gold metal films by applying a current to the first connection pad 121 including copper. For another example, the first conductive layer 141 may be formed by an electroless gold plating method.

The width of the first conductive layer 141 may be equal to or greater than the width of the first connection pad 121 on the cross-section in a thickness direction of the circuit board 100. The width of the first conductive layer 141 may be equal to or greater than the width of the first connection pad 121 on a portion where the first conductive layer 141 contacts the first connection pad 121.

The first connection pad 121 may be a bond finger disposed in a bond finger region, and a plurality of the first connection pads 121 may configure a plurality of bond fingers. That is, the first connection pad 121 may be configured with the bond finger for a wire bonding pad, and a conductive wire may be bonded to the same when wire-bonding the semiconductor chip.

A first protection layer 131 may be disposed on the first surface 110a of the insulating layer 110. The first protection layer 131 may be opened to expose the first connection pad 121. The first protection layer 131 may overlap the first circuit wiring 122 disposed in the insulating layer 110 and may cover the same. The first protection layer 131 may be formed of a solder resist layer.

Regarding the thickness in the direction that is perpendicular to the first surface 110a of the insulating layer 110, the thickness of the first circuit wiring 122 may be greater than the thickness of the first portion 121a of the first connection pad 121. The entire thickness of the first connection pad 121 including the first portion 121a and the second portion 121b may be equal to the thickness of the first circuit wiring 122.

A second connection pad 125 and a second circuit wiring 126 may be further formed on the second surface 110b of the insulating layer 110. The second connection pad 125 and the second circuit wiring 126 may protrude on the second surface 110b of the insulating layer 110, and may be connected to the first circuit wiring 122 through a via 123. A second protection layer 135 may be formed around the second connection pad 125 on the second surface 110b of the insulating layer 110. The second protection layer 135 may overlap the second circuit wiring 126 and may cover the same, and may be formed of the solder resist layer.

The second connection pad 125 and the second circuit wiring 126 may include a copper (Cu) layer, and a second conductive layer 145 may be formed on the second connection pad 125. The second conductive layer 145 may include a nickel (Ni) plating layer and a gold (Au) plating layer. The nickel plating layer may be formed on the second connection pad 125, and the gold plating layer may be formed on the nickel plating layer.

The circuit board 100 shown in FIG. 1 shows a structure having connection pads 121 and 125 on respective surfaces of the insulating layer 110, and alternatively, the second connection pad 125 disposed on the second surface 110b of the insulating layer 110 may be omitted, according to some aspect of the present disclosure. The insulating layer 110 may include a plurality of insulating layers, and the plurality of insulating layers may include a plurality of circuit layer, respectively. Therefore, the circuit layer may be respectively formed on the insulating layer with at least three layers, and a via may extend in the thickness direction of the insulating layer to connect the circuit layers.

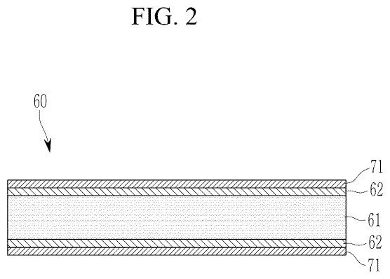

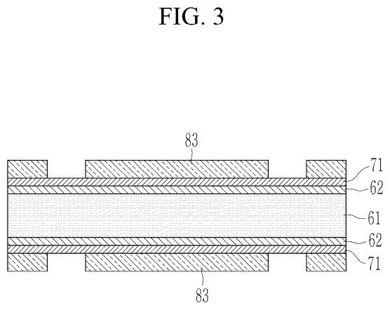

FIG. 2 to FIG. 15 show process cross-sectional views on a method for fabricating a circuit board shown in FIG. 1. The method for fabricating a circuit board will now be described with reference to FIG. 2 to FIG. 15 together with FIG. 1.

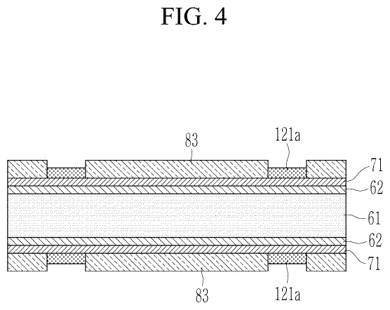

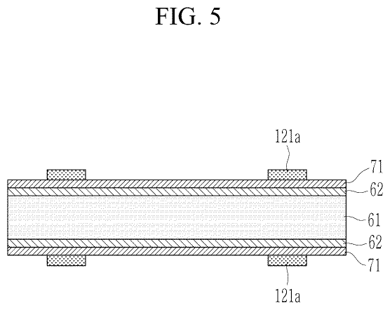

Referring to FIG. 2 to FIG. 5, a carrier substrate 60 on which a first seed layer 71 is disposed is provided on at least one surface, and a first portion 121a of the first connection pad 121 is formed on the first seed layer 71 according to a circuit forming process. The carrier substrate 60 may represent a substrate in which a copper foil layer 62 is stacked on respective sides of the insulation substrate 61, and the first seed layer 71 may be separated from the copper foil layer 62 (see FIG. 2). A first plating resist pattern 83 may be formed by exposing and developing a plating resist formed on the carrier substrate 60. The first plating resist pattern 83 may be formed by removing only a portion where a first portion 121a of the first connection pad 121 is to be formed. The first portion 121a of the first connection pad 121 may be formed by plating a conductive metal on the portion of the first seed layer 71 exposed through an opening of the patterned first plating resist pattern 83 (see FIG. 4). The first plating resist pattern 83 is removed when the first portion 121a of the first connection pad 121 is formed (see FIG. 5).

Any materials used as conductive metals for circuits in the circuit board field are usable to the first seed layer 71, and the copper (Cu) is generally used. The first portion 121a of the first connection pad 121 may be connected to the first seed layer 71 of the carrier substrate 60 and may include the same type of metal as the first seed layer 71. For example, the first seed layer 71 and the first portion 121a of the first connection pad 121 may include copper (Cu).

The present embodiment shows that the first portion 121a of the first connection pad 121 is formed on the respective surfaces of the carrier substrate 60, and the first portion 121a of the first connection pad 121 may also be formed on one surface of the carrier substrate 60, according to some aspect of the present disclosure.

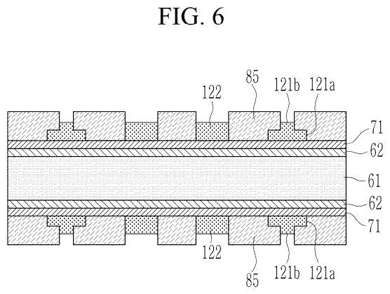

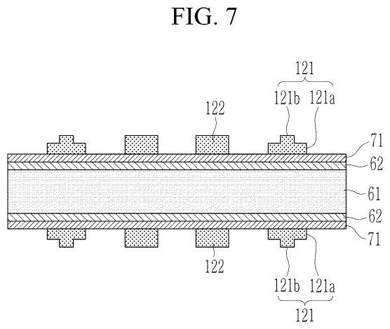

Referring to FIG. 6 and FIG. 7, a second plating resist pattern 85 from which a portion where the second portion 121b of the first connection pad 121 will be formed is removed through exposure and development may be formed on the carrier substrate 60 on which the first portion 121a of the first connection pad 121 is formed. The second portion 121b of the first connection pad 121 may be formed by plating a conductive metal on the first portion 121a of the first connection pad 121 exposed through the opening of the patterned second plating resist pattern 85 (see FIG. 6). In this instance, the second plating resist pattern 85 may be opened in a portion of the first seed layer 71 on which the first portion 121a of the first connection pad 121 is not formed. The conductive metal may be plated on the first seed layer 71, and the first circuit wiring 122 may be formed on the portion. The second plating resist pattern 85 is removed when the first circuit wiring 122 and the second portion 121b of the first connection pad 121 are formed (see FIG. 7).

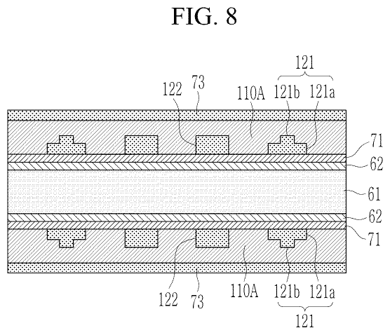

Referring to FIG. 8, an insulating layer 110A is stacked to embed the first connection pad 121, and a second seed layer 73 is formed on an upper surface of the insulating layer 110A. The second seed layer 73 may be provided to form the second connection pad 125 and the second circuit wiring 126, any types of conductive metals are usable without limits, and copper (Cu) is generally used.

The insulating layer 110A may include a resin insulating layer. The insulating layer 110A may use a thermo-curable resin such as an epoxy resin, a thermoplastic resin such as a polyimide, or a resin, e.g., a prepreg, to which a reinforcing member such as glass fibers or an inorganic filler is impregnated, and may include a thermo-curable resin and/or a photocurable resin, and it is not limited thereto.

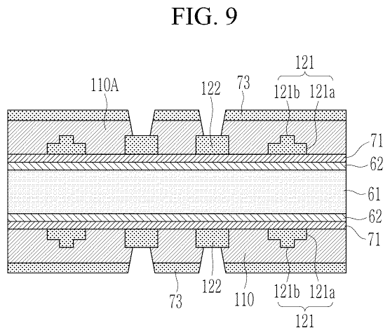

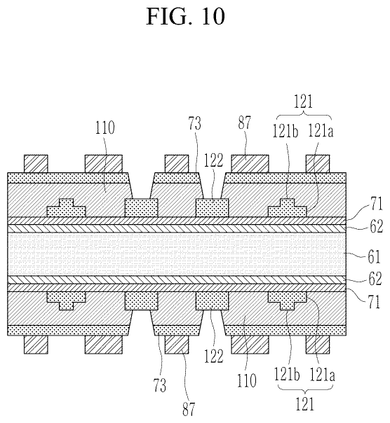

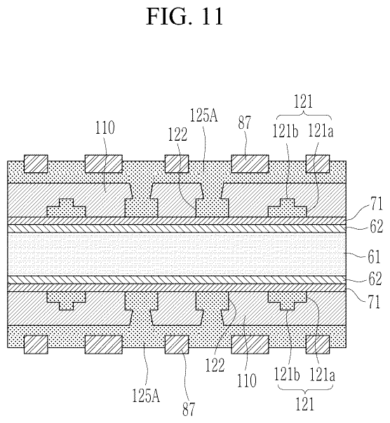

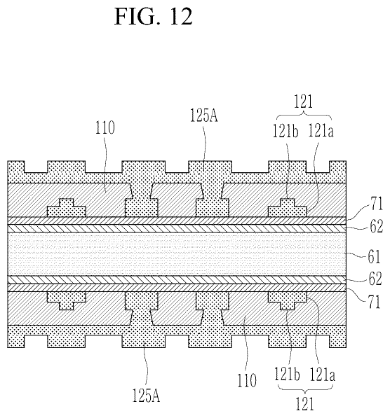

Referring to FIG. 9 to FIG. 12, a wire pattern layer 125A for forming the second connection pad 125 and the second circuit wiring 126 may be formed on the insulating layer 110 according to a circuit forming process. The wire pattern layer 125A may include a same type of material as the first circuit wiring 122 and the first connection pad 121. In this instance, to form the via 123 for connecting the first circuit wiring 122 and the wire pattern layer 125A, the insulating layer 110 may be partly etched to expose a portion of the first circuit wiring 122 (see FIG. 9). A third plating resist pattern 87 may be formed on the second seed layer 73 to form the wire pattern layer 125A (see FIG. 10). A portion of the third plating resist pattern 87, on which the wire pattern layer 125A will be formed, may be opened and the second seed layer 73 may be exposed. A plating process may be performed on the exposed second seed layer 73 and the portion of the first circuit wiring 122 (see FIG. 11). When the wire pattern layer 125A is formed, the third plating resist pattern 87 may be removed and an embedded pattern substrate portion may be completed on respective sides of the carrier substrate 60 (see FIG. 12).

According to the shown embodiment, each the embedded pattern substrate portion is shown to include one insulating layer 110 and a first circuit wiring 122 and a second circuit wiring 126 that are two metal layers, and without being limited thereto, it may include a greater number of build-up insulating layers and build-up wire pattern layers, which belongs to the range of the present disclosure.

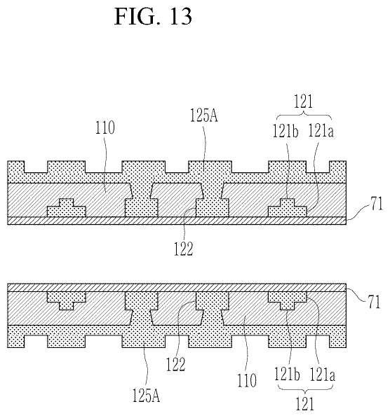

Referring to FIG. 13, an embedded pattern substrate is provided by separating the first seed layer 71 and the carrier substrate 60. One pair of embedded pattern substrates may be obtained by separating the first seed layer 71 formed on respective surfaces of the carrier substrate 60 from the copper foil layer 62, and individual processes may be applied to the one pair of embedded pattern substrates.

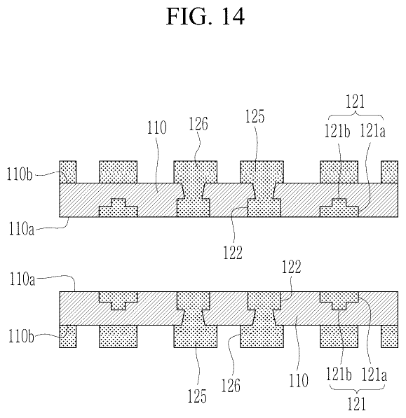

Referring to FIG. 14, the embedded pattern substrate obtained in FIG. 13 is soft-etched to remove the first seed layer 71 and the second seed layer 73. When the first seed layer 71 and the second seed layer 73 are removed, the first connection pad 121 and the first circuit wiring 122 embedded in the insulating layer 110 and exposed toward the first surface 110a are formed. The wire pattern layer 125A disposed on the second surface 110b of the insulating layer 110 is separated from each other to form the second connection pad 125 and the second circuit wiring 126. By removing the first seed layer 71, a portion of the first portion 121a of the first connection pad 121 may be exposed from the insulating layer 110. In the process for removing the first seed layer 71, surfaces of the first connection pad 121 and the first circuit wiring 122 exposed from the insulating layer 110 may be partly etched and may be dented in the surface of the insulating layer 110.

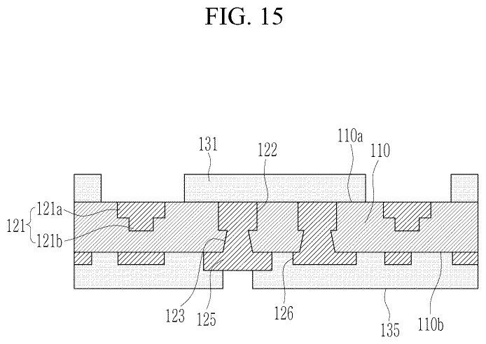

Referring to FIG. 15, a first protection layer 131 and a second protection layer 135 are formed on respective surfaces of the embedded pattern substrate obtained in FIG. 14 to cover the insulating layer 110 and the circuit wirings 122 and 126. The first protection layer 131 and the second protection layer 135 may include a solder resist layer. The first protection layer 131 may be patterned so that the first connection pad 121 may be exposed on the first surface 110a of the insulating layer 110 on which the first connection pad 121 is exposed. The second protection layer 135 may be opened in the second surface 110b of the insulating layer 110 on which the second connection pad 125 is disposed to cover the second circuit wiring 126 and expose the second connection pad 125.

Referring to FIG. 1, a first conductive layer 141 and a second conductive layer 145 may be formed on the first connection pad 121 and the second connection pad 125 exposed by the protection layers 131 and 135 on the embedded pattern substrate obtained in FIG. 15. The first conductive layer 141 and the second conductive layer 145 may be formed by a gold electroplating method. The nickel plating layer and the gold plating layer may be formed by forming the nickel/gold metal films by applying a current to the first connection pad 121 or the second connection pad 125 including copper. Optionally, the first conductive layer 141 and the second conductive layer 145 may be formed by the electroless gold plating method.

While this invention has been described in connection with what is presently considered to be practical examples, it is to be understood that the invention is not limited to the disclosed embodiments, but, on the contrary, is intended to cover various modifications and equivalent arrangements included within the spirit and scope of the appended claims.

What is claimed is:

1. A circuit board comprising:
an insulating layer having a first surface and a second surface opposing each other; and
a first connection pad having a first portion embedded in the insulating layer and at least partly exposed from the insulating layer on the first surface and a second portion closer to the second surface than the first portion,
wherein, a first width of the first portion in a direction parallel to the first surface is different from a second width of the second portion in the direction parallel to the first surface.

2. The circuit board of claim 1, wherein
the first width is greater than the second width.

3. The circuit board of claim 1, wherein
the first portion and the second portion are configured to have a step.

4. The circuit board of claim 1, further comprising
a protection layer disposed on the first surface of the insulating layer and having an opening to expose the first connection pad.

5. The circuit board of claim 4, further comprising
a first circuit wiring embedded in the insulating layer and covered with the protection layer,
wherein a thickness of the first circuit wiring in a direction perpendicular to the first surface is greater than a thickness of the first portion of the first connection pad in the direction perpendicular to the first surface.

6. The circuit board of claim 1, further comprising
a conductive layer disposed on the first connection pad.

7. The circuit board of claim 6, wherein
the conductive layer is disposed on the exposed portion of the first connection pad.

8. The circuit board of claim 6, wherein
the conductive layer protrudes on the first surface of the insulating layer.

9. The circuit board of claim 6, wherein
a width of the conductive layer in the direction parallel to the first surface is greater than the second width of the second portion of the first connection pad.

10. The circuit board of claim 6, wherein
a width of the conductive layer in the direction parallel to the first surface is equal to or greater than the first width of the first portion of the first connection pad.

11. The circuit board of claim 6, wherein
the conductive layer includes a gold (Au) plating layer.

12. The circuit board of claim 1, wherein
the first connection pad includes copper (Cu).

13. The circuit board of claim 1, wherein
the first connection pad is disposed in a bond finger region.

14. The circuit board of claim 1, further comprising
a second connection pad disposed on the second surface of the insulating layer.

15. The circuit board of claim 1, wherein
the insulating layer includes a plurality of insulating layers, and
the circuit board further comprises a plurality of circuit layers disposed in or on the plurality of insulating layers.

16. A method for fabricating a circuit board comprising:
forming a first portion of a first connection pad with a first metal on a seed layer;
forming a second portion of the first connection pad having a different width from the first portion on the first portion by patterning plating resist covering a portion of the first portion and plating the first metal; and
forming an insulating layer to cover the first portion and the second portion.

17. The method of claim 16, wherein
a first width of the first portion is formed to be greater than a second width of the second portion.

18. The method of claim 16, further comprising
removing the seed layer to expose at least a portion of the first portion from the insulating layer.

19. The method of claim 18, further comprising
forming a conductive layer on the first portion exposed from the insulating layer.

20. The method of claim 19, further comprising
forming, on the insulating layer, a protection layer having an opening to expose the conductive layer.
